(19) United States
(12) Patent Application Publication
(10) Pub. No.: US 2009/0181475 A1
(43) Pub. Date: Jul. 16, 2009

(54) DETECTING THE PRESENCE OF A WORKPIECE RELATIVE TO A CARRIER HEAD

(75) Inventor: Toru AKASAKO, San Jose, CA (US)

Correspondence Address: INGRASSIA FISHER & LORENZ, P.C. (NVLS), 7010 EAST COCHISE ROAD, SCOTTSDALE, AZ, 85253-1406, US

(73) Assignee: NOVELLUS SYSTEMS, INC., San Jose, CA (US)

(21) Appl. No.: 12/013,007

(22) Filed: Jan. 11, 2008

(51) Int. Cl. H01L 21/00; B24B 5/00; H01L 21/302

(52) U.S. Cl. 438/5; 451/285; 438/692

(57) ABSTRACT

A carrier head for a workpiece includes a capacitive sensor that is configured to detect the presence of the workpiece during a chemical mechanical planarization/polishing procedure. The sensor subsystem can detect a wafer unloaded condition, a wafer loaded condition, and different in-process conditions that might occur during processing of the wafer. One embodiment of such a carrier head includes a body, a structure coupled to the body, and a capacitive sensor coupled to the body. The structure is configured to hold a workpiece such as a semiconductor wafer. The capacitive sensor is configured to generate an analog output that indicates the workpiece presence status relative to the carrier head.

### CROSS-REFERENCE TO RELATED APPLICATION(S)

The subject matter of this application is related to the subject matter disclosed in U.S. patent application Ser. No. 11/553,572, titled Carrier Head for Workpiece Planarization/Polishing.

### TECHNICAL FIELD

Embodiments of the subject matter described herein relate generally to workpiece processing. More particularly, embodiments of the subject matter relate to detecting the presence of a workpiece, such as a semiconductor wafer, in a carrier head of a chemical mechanical planarization/polishing system.

### BACKGROUND

For a variety of workpieces (e.g., semiconductor wafers, optical blanks, memory disks, etc.), manufacture requires the substantial planarization of at least one major workpiece surface. For ease of description and understanding, the following description will concentrate on exemplary embodiments that are pertinent to semiconductor wafers. It should be understood, however, that a carrier head as described herein may be utilized to planarize a wide variety of workpieces in addition to semiconductor wafers. Furthermore, as appearing herein, the term “planarization” is used in its broadest sense and includes any chemical and/or mechanical process that may be utilized to smooth (e.g., remove irregular topographical features from, change the thickness of, etc.) or polish the surface of a workpiece.

The technique of chemical mechanical polishing, also known as chemical mechanical planarization (referred to herein collectively as “CMP”), has been widely adopted for the planarization of semiconductor wafers. CMP processes produce a substantially smooth, planar face along a major surface of the wafer (referred to herein as the wafer's front surface) to prepare the workpiece surface for subsequent fabrication processes (e.g., photoresist coating, pattern definition, etc.). During CMP, an unprocessed wafer is transferred to a carrier head, which then presses the wafer against a polishing surface (e.g., a polish pad) supported by a platen. Polishing slurry is introduced between the wafer's front surface and the polish pad (e.g., via conduits provided through the polish pad and/or a dispenser located above the polish pad), and relative motion (e.g., rotational, orbital, and/or linear) is initiated between the polish pad and the wafer carrier. The mechanical abrasion of the polish pad and the chemical interaction of the slurry produce a substantially planar topography along the wafer's front surface.

One known type of carrier head generally includes a flexible membrane or bladder that contacts the back (i.e., the unpolished) surface of the work piece during the CMP process. Multiple pressure chambers or plenums are provided behind the bladder to form a number of annular pressure zones across the bladder's working face. The pressure within each zone is independently adjusted to vary the force applied to the wafer's back surface at different locations. Occasionally, the wafer is improperly positioned in the carrier or the bladder does not properly create suction to the wafer in the carrier head. It is important to verify that the wafer is properly held before the start of the polishing process to prevent damage to the wafer or the polishing tool. In this regard, a sensor can be utilized to detect the presence of a wafer in the carrier head. A carrier head that incorporates a capacitive sensor (for wafer presence detection) is disclosed in U.S. Pat. No. 6,568,991.

The wafer detection technique disclosed in U.S. Pat. No. 6,568,991 can distinguish between two wafer presence states: wafer unloaded and wafer loaded. This technique is practical and effective at detecting these two states. However, this technique is unable to determine other in-process states that might arise during polishing of the wafer, such as a broken wafer, a loose wafer, the beginning and end of a wafer “burping” cycle, abnormal process conditions, wafer purging, etc. Moreover, the capacitive sensor utilized by this technique can be sensitive to the presence of water on or near the bladder. In other words, the presence of a film of water on the bladder might result in a false wafer detection even though a wafer is not actually loaded onto the carrier head.

### BRIEF SUMMARY

A carrier head for a CMP system and related operating methods are provided. The carrier head utilizes a sensor that detects the proximity of a workpiece relative to the carrier head. The sensor subsystem is capable of generating a continuous analog output that ranges between a first output level corresponding to a wafer unloaded condition and a second output level corresponding to a wafer loaded condition. Different output levels and/or certain output signal characteristics can also be analyzed to detect corresponding in-process conditions.

The above and other aspects may be found in an embodiment of a carrier head for supporting a workpiece. The carrier head includes a body, a structure coupled to the body, the structure being configured to hold a workpiece, and a capacitive sensor coupled to the body. The capacitive sensor is configured to generate an analog output that indicates workpiece presence status relative to the carrier head. The status can include a workpiece unloaded status, a workpiece loaded status, and at least one workpiece in-process status.

The above and other aspects may be carried out by an embodiment of a method of controlling a CMP process for a workpiece. The method involves: obtaining a workpiece presence signal that indicates proximity of the workpiece to a carrier head of a CMP system; identifying an attribute of the workpiece presence signal, the attribute being indicative of a CMP process status of the workpiece; and controlling operation of the CMP system in a manner dictated by the attribute.

The above and other aspects may be found in an embodiment of a CMP system having a polishing pad for polishing a workpiece, a carrier head configured to hold the workpiece against the polishing pad during planarization, and to hold the workpiece during transport to and from the polishing pad, a capacitive sensor coupled to the carrier head and configured to produce a workpiece presence signal that indicates proximity of the workpiece to the carrier head, and a processing architecture coupled to the capacitive sensor. The processing architecture is configured to receive the workpiece presence signal, detect CMP process related attributes of the workpiece presence signal, and control operation of the CMP system in response to detected CMP process related attributes.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1A is a simplified cross sectional view of a carrier head and a polishing platen of an orbital CMP system;

FIG. 1B is a simplified cross sectional view of a carrier head and a polishing platen of a rotational CMP system;

FIG. 2 is an isometric view of an embodiment of a carrier head;

FIG. 3 is a cross sectional view of the carrier head shown in FIG. 2;

FIG. 4 is an isometric cross sectional view of the bladder of the carrier head shown in FIG. 2;

FIG. 5 is a schematic representation of an embodiment of a workpiece detection subsystem suitable for use with a CMP system;

FIG. 6 is a graph that shows a typical plot of detection sensor output versus time for a CMP procedure;

FIG. 7 is a graph that shows a typical plot of detection sensor output versus time for a CMP procedure during which the wafer is almost lost prior to unloading;

FIG. 8 is a graph that shows a typical plot of detection sensor output versus time for a CMP procedure during which the wafer separates from the polishing pad;

FIG. 9 is a graph that shows a typical plot of detection sensor output versus time for a CMP procedure during which the wafer becomes broken;

FIG. 10 is a flow chart that illustrates an embodiment of a method of controlling a CMP procedure; and

FIG. 11 is a schematic circuit diagram that illustrates an exemplary capacitive sensor deployed in a CMP system.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Techniques and technologies may be described herein in terms of functional and/or logical block components, and with reference to symbolic representations of operations, processing tasks, and functions that may be performed by various computing components or devices. Such operations, tasks, and functions are sometimes referred to as being computer-executed, computerized, software-implemented, or computer-implemented. In practice, one or more processor devices can carry out the described operations, tasks, and functions by manipulating electrical signals representing data bits at memory locations in the system memory, as well as other processing of signals. The memory locations where data bits are maintained are physical locations that have particular electrical, magnetic, optical, or organic properties corresponding to the data bits. It should be appreciated that the various block components shown in the figures may be realized by any number of hardware, software, and/or firmware components configured to perform the specified functions. For example, an embodiment of a system or a component may employ various integrated circuit components, e.g., memory elements, digital signal processing elements, logic elements, look-up tables, or the like, which may carry out a variety of functions under the control of one or more microprocessors or other control devices.

The following description may refer to elements or nodes or features being “connected” or “coupled” together. As used herein, unless expressly stated otherwise, “connected” means that one element/node/feature is directly joined to (or directly communicates with) another element/node/feature, and not necessarily mechanically. Likewise, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

For the sake of brevity, conventional techniques related to semiconductor wafer processing, chemical mechanical planarization/polishing, capacitive sensors, and other functional aspects of the systems (and the individual operating components of the systems) may not be described in detail herein.

The carrier head and workpiece detection techniques and technologies described herein are suitable for use with a CMP system that processes semiconductor wafers. Appropriate CMP systems are disclosed in U.S. Pat. No. 7,229,339, U.S. Pat. No. 6,568,991, and U.S. patent application Ser. No. 11/553,572, titled Carrier Head for Workpiece Planarization/Polishing (the relevant content of these documents is incorporated by reference herein). Briefly, a CMP system uses one or more carrier heads to transport wafers to and from a polishing pad located on a platen. A carrier head is also used to hold a wafer against the polishing pad during the polishing/planarizing portion of the CMP procedure. CMP systems and their operation will not be described in detail here.

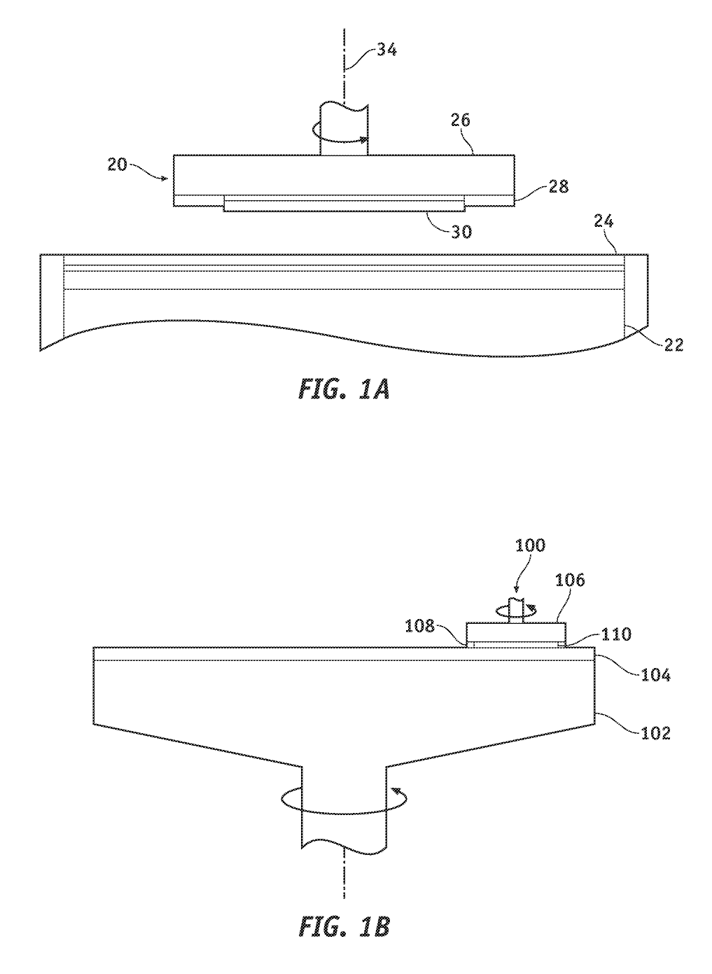

FIG. 1A is a simplified cross sectional view of a carrier head 20 and a polishing platen 22 of an orbital CMP system, and FIG. 1B is a simplified cross sectional view of a carrier head 100 and a polishing platen 102 of a rotational CMP system. Polishing platen 22/102 supports a polishing element or surface, such as a polishing pad 24/104. Carrier head 20/100 generally includes a body 26/106 and a retaining ring 28/108, which retains a wafer 30/110 during polishing. Carrier head 20/100 includes structure that holds the wafer 30/110 against polishing pad 24/104 during planarization, and holds the wafer 30/110 during transport to and from polishing pad 24/104. The CMP system in FIG. 1B may also include a slurry distribution apparatus to supply a polishing fluid to a top surface of polishing pad 104. Carrier head 20/100 is suitably configured to cause the wafer 30/110 to rotate, orbit, and/or translate, and to retain the wafer 30/110. In addition, carrier head 20/100 is configured to force the wafer 30/110 against polishing pad 24/104 during the CMP process.

For the orbital CMP system, polishing platen 22 is generally configured to move polishing pad 24 in an orbital manner, while carrier head 20 rotates wafer 30 about an axis 34 (as depicted in FIG. 1A). For the rotational CMP system, polishing platen 102 is generally configured to move polishing pad 104 via rotation about its axis (as depicted in FIG. 1B). Generally, carrier head 20/100 also rotates, while simultaneously moving polishing platen 22/102 and polishing pad 24/104. In accordance with one exemplary embodiment, carrier head 20/100 moves wafer 30/110 in both a rotational and a translational direction during the polishing process. In accordance with another embodiment, carrier head 20/100 orbits about an axis.

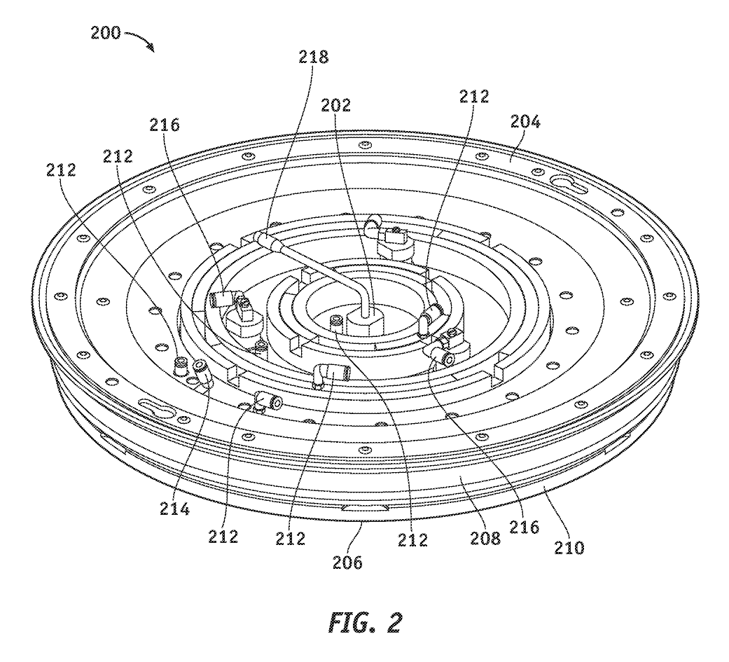

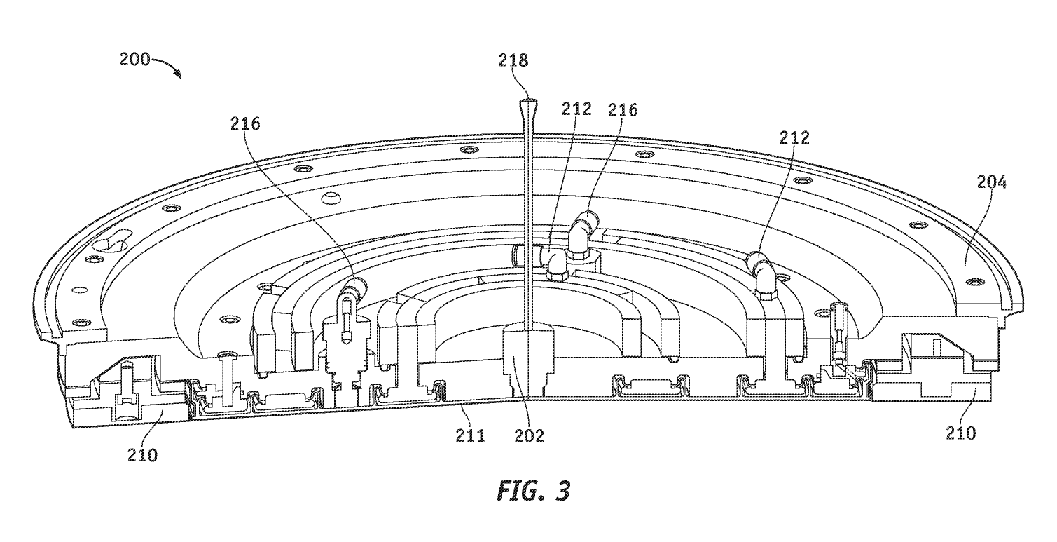

Although not separately depicted in FIG. 1A or FIG. 1B, an embodiment of carrier head 20/100 may include a workpiece detection sensor coupled to the body 26/106. FIG. 2 (which is an isometric view of an embodiment of a carrier head 200) shows a workpiece detection sensor 202 for carrier head 200. FIG. 3 is a cross sectional view of carrier head 200.

Carrier head 200 may be generally disc-like in shape and comprises an upper surface 204, a lower surface 206, and an annular rim portion 208. The outer annular portion of lower surface 206 is defined by a retaining ring 210 (also referred to as a wear ring). Retaining ring 210 encircles a flexible bladder 211 (hidden from view in FIG. 2) and pre-stresses or pre-compresses the polish pad to protect the leading edge of the workpiece during polishing. The body/housing of carrier head 200 cooperates with the bladder 211 to form a plurality (e.g., six) of pressure chambers or plenums. The pressure within each of these plenums may be independently manipulated to vary the pressure applied by the bladder to the wafer's back surface. A plurality of pneumatic fittings 212 permit the plenums to be fluidly coupled to an external source of pressure (e.g., via flexible connector tubing). Each fitting 212 is associated with a different pressure plenum. In the illustrated embodiment, carrier head 200 comprises six fittings 212 corresponding to six bladder plenums, and a seventh pneumatic fitting 214 corresponding to a retaining ring plenum. In addition to pneumatic fittings 212 and 214, carrier head 200 is provided with a plurality of pneumatic fittings 216, which allow a plurality (e.g., three) of ejectment mechanisms to be fluidly coupled to an external source of pressure.

As mentioned above, carrier head 200 is also provided with a workpiece detection sensor 202, which may be disposed through a central portion of carrier head 200 as shown in FIG. 3. Workpiece detection sensor 202 may be operatively coupled to a workpiece detection subsystem (not shown in FIG. 2 or FIG. 3) that is suitably configured to obtain, monitor, analyze, interpret, and/or otherwise process output signals generated by workpiece detection sensor 202. In this regard, carrier head 200 may employ a conduit 218, cable, connector, or other element that is configured to conduct the electrical signals utilized by workpiece detection sensor 202.

For this embodiment, workpiece detection sensor 202 takes the form of a capacitive sensor. The capacitive sensor generally operates in accordance with known principles. In particular, an electrical excitation signal is applied to a capacitive element having a variable capacitance that changes when the electric field of the capacitive element is disturbed. In the context of this particular application, disturbance of the electric field is caused by the presence of the wafer near the capacitive sensor. If no wafer (or other non-insulating object) is located near the capacitive sensor, then the electric field generated by the capacitive element will not be disturbed and the capacitance will be relatively high. On the other hand, if a wafer (or other non-insulating object) is within close proximity of the capacitive sensor, then the electric field will be affected and the capacitance will be lowered. In practice, workpiece detection sensor 202 cooperates with a suitably configured receiver/processor component that measures the capacitance of the capacitive element (in real time or substantially real time) and generates an analog output signal in response to the changing capacitance. Thus, workpiece detection sensor 202 is capable of generating an analog output that indicates workpiece presence status relative to carrier head 200. For example, workpiece detection sensor 202 generates an analog output that indicates a workpiece unloaded status, a workpiece loaded status, and at least one workpiece in-process status, where an “in-process” status refers to a status that occurs between loading and unloading of the workpiece. The analog output produced by workpiece detection sensor 202 may also be referred to herein as a “workpiece presence signal.” This workpiece presence signal, which can be monitored, processed, and/or analyzed in the manner described in more detail below, indicates proximity of the workpiece to carrier head 200.

In certain embodiments, workpiece detection sensor 202 generates an output voltage having a magnitude that varies with the distance between sensor 202 and the workpiece. Sensor 202 can generate a continuous range of output voltages between a first voltage corresponding to a workpiece unloaded status and a second voltage corresponding to a workpiece loaded status. In other words, the loaded and unloaded conditions may represent the output range of sensor 202, and different in-process conditions may result in distinguishable voltages and/or workpiece presence signal attributes that fall within this output range. In other system embodiments, the detected or measured output range limits of sensor 202 may correspond to conditions other than “workpiece loaded” and “workpiece unloaded.”

Notably, workpiece detection sensor 202 is not limited to only two detection states (workpiece loaded or unloaded), and sensor 202 can generate a range of output values that indicate different operating states and conditions of the CMP procedure. Moreover, exemplary embodiments of carrier head 200 employ a capacitive sensor that is suitably configured to be insensitive to the presence of water (and/or other fluids such as polishing slurry). Thus, a liquid film or layer of water near sensor 202 will not create a false wafer detection. Consequently, carrier head 200 need not include safeguards or features that are intended to eliminate false wafer detections due to water. For example, carrier head 200 need not inflate its bladder 211 to distance water or other liquids away from sensor 202 during measurements.

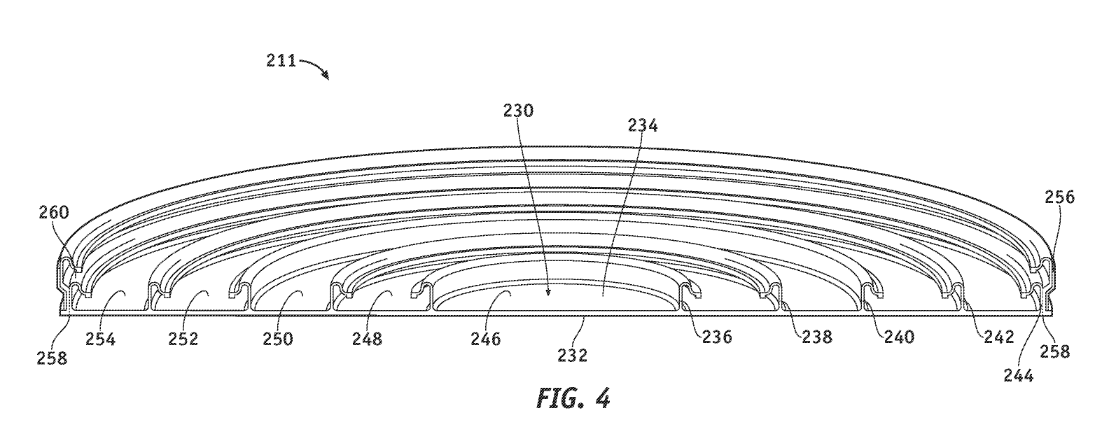

For this particular embodiment, workpiece detection sensor 202 is mounted at or near the center of the body of carrier head 200, and the sensing surface is oriented toward bladder 21 1. More specifically, bladder 211 covers sensor 202, as depicted in FIG. 3. One non-limiting embodiment of bladder 211 is shown in more detail in FIG. 4, which is a cross-sectional, isometric view of bladder 21 1. In practice, other bladder types and different embodiments of bladder 211 may be utilized.

Bladder 211 comprises a flexible base diaphragm 230 having a first working surface 232, which contacts a workpiece (e.g., a semiconductor wafer) during planarization/polishing, and a second surface 234 opposite surface 232. A plurality of annular ribs (e.g., five) extends from surface 234 to partially define a plurality (e.g., five) of concentric pressure chambers or plenums. Working outward from the center of bladder 211, the ribs are numbered 236, 238, 240, 242, and 244. Similarly, the plenums are numbered 246, 248, 250, 252, and 254. Plenum 246 is laterally defined by rib 236, plenum 248 by ribs 236 and 238, plenum 250 by ribs 238 and 240, plenum 252 by ribs 240 and 242, and plenum 254 by ribs 242 and 244.

It will be noted that bladder 211 includes an additional rib 256 disposed along the outer circumference of diaphragm 230. Rib 256 extends from the upper peripheral edge of bladder 211 to the lower peripheral edge of bladder 211. An inner surface of rib 256 is coupled (e.g., integrally) to an outer annular surface of rib 244, and an end portion of rib 256 is coupled to the outer peripheral edge of diaphragm 230. To help distinguish rib 256 in FIG. 4, dotted lines 258 separate rib 256 from rib 244 and from diaphragm 230. Rib 256 cooperates with an upper portion of rib 244 to partially define an additional plenum 260. As suggested by its peripheral disposition of rib 256, plenum 260 and rib 256 are utilized to control the outer edge of diaphragm 230 during planarization/polishing. Plenum 260 may be selectively pressurized to control the vertical displacement of rib 256 and, therefore, the planarization/polishing characteristics (e.g., the rate of removal) along the outer edge of a wafer during CMP processing.

The annular ribs may be integrally formed with diaphragm 230 and may each comprise a vertical column having first and second substantially opposite end portions. The annular ribs are preferably oriented substantially orthogonally to the plane of diaphragm 230. In preferred embodiments, each annular rib comprises a strain relief member (e.g., an annular brim having a generally J-shaped cross-section) disposed intermediate the first and second end portions. The strain relief members permit greater vertical displacement of the annular ribs and, consequently, permit a greater range of motion substantially orthogonally to working surface 232 (referred to as a “longer throw”). However, it will be appreciated by one skilled in the art that any or all of the provision of strain relief members is optional and, similarly, that each of the annular ribs may assume a variety of other shapes (e.g., an annular lip having a generally L-shaped cross-section) suitable for attachment to the housing of carrier head 200.

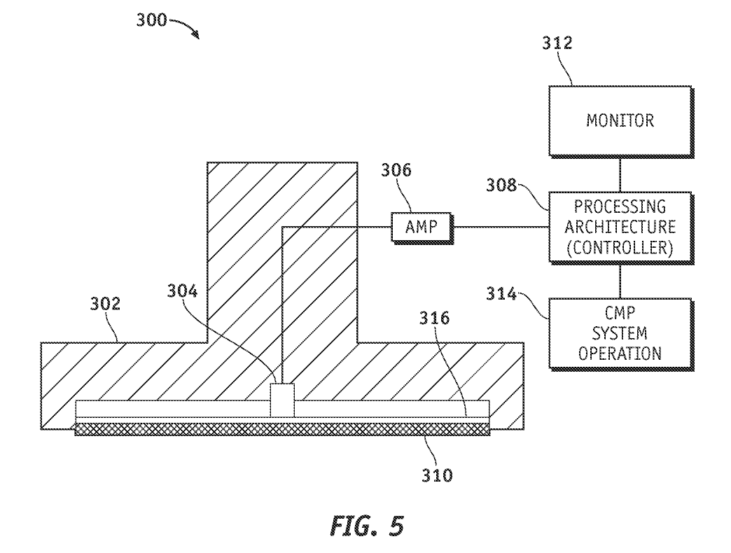

FIG. 5 is a schematic representation of an embodiment of a workpiece detection subsystem 300 suitable for use with a CMP system. Subsystem 300 includes, without limitation: a carrier head 302; a workpiece detection sensor 304; an amplifier 306; and a processing architecture 308 (which may include or be realized as a controller for the CMP system). For ease of description, FIG. 5 also depicts a wafer 310 loaded in carrier head 302. FIG. 5 also includes a block corresponding to a monitoring function 312 of the CMP system, and a block corresponding to CMP system operation logic 3 14.

Workpiece detection subsystem 300 is suitably configured to detect CMP procedure conditions associated with the status of wafer 310 relative to carrier head 302. As described above, a membrane or bladder 316 may be positioned between sensor 304 and wafer 310. The bladder 316 is used to support the back surface of the wafer 310 during the polishing process. For this embodiment, the size of capacitive sensor 304 (e.g., an analog capacitive sensor) may be reduced by positioning its amplifier 306 remotely. Here, the sensor 304 is preferably connected to processing architecture 308, which acts upon the information acquired from sensor 304. A remote sensor amplifier 306 also improves physical access to the amplifier 306 during calibration procedures. The gain of the amplifier 306 is adjusted during calibration until the sensor 304 can easily distinguish between desired conditions of interest. The communication path between the sensor 304 and the processing architecture 308 may use, for example, electrical wire, fiber optics or wireless radio technology.

Processing architecture 308 may be realized as the main processing component of the host CMP system, or it may be a separate processing component that is devoted to workpiece detection subsystem 300. Processing architecture 308 is suitably configured to receive the workpiece presence signal generated by sensor 304 (or an amplified or converted version thereof), and detect CMP procedure related attributes of the workpiece presence signal. Processing architecture 308 may also be configured to control operation of the CMP system, using CMP system operation logic 314, in response to the detected CMP procedure related attributes. For example, processing architecture 308 can analyze the workpiece presence signal to determine whether wafer 310 is properly loaded (as shown in FIG. 5), unloaded, incorrectly loaded, etc. Moreover, processing architecture 308 can analyze the workpiece presence signal to detect abnormal operating conditions during a CMP procedure. Such abnormal operating conditions may include, without limitation: improper wafer loading; wafer separation from the polishing pad during the polishing procedure; loss or partial loss of the wafer during transport to/from the polishing pad; wafer breakage during the polishing procedure; etc.

As used herein, an “attribute” of a workpiece presence signal is any measurable, detectable, calculable, or observable feature, value, trend, slope, characteristic, waveform, shape, or pattern of the workpiece presence signal. Examples of such attributes include, without limitation: a particular voltage level; a local or global minima or maxima; an abrupt rise or fall in the signal; a change in the rising or falling slope in the signal; or the like. An embodiment of the system described herein may utilize waveform analysis, signal processing, averaging, and/or comparison techniques to analyze, detect, and identify certain attributes of interest.

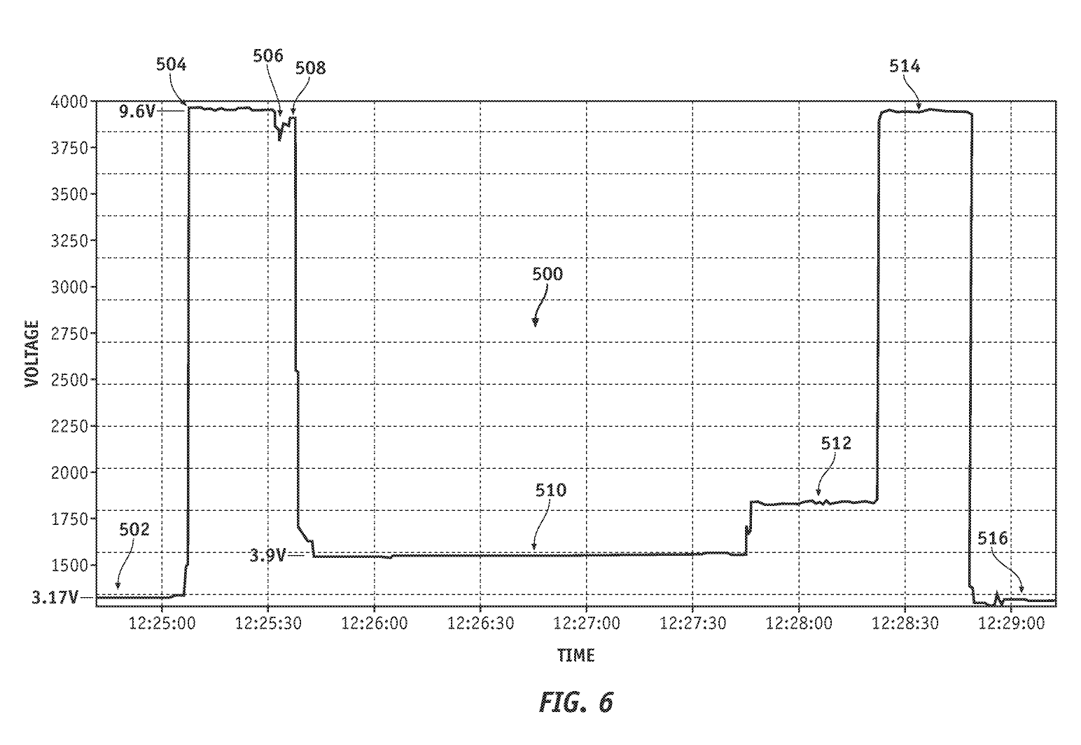

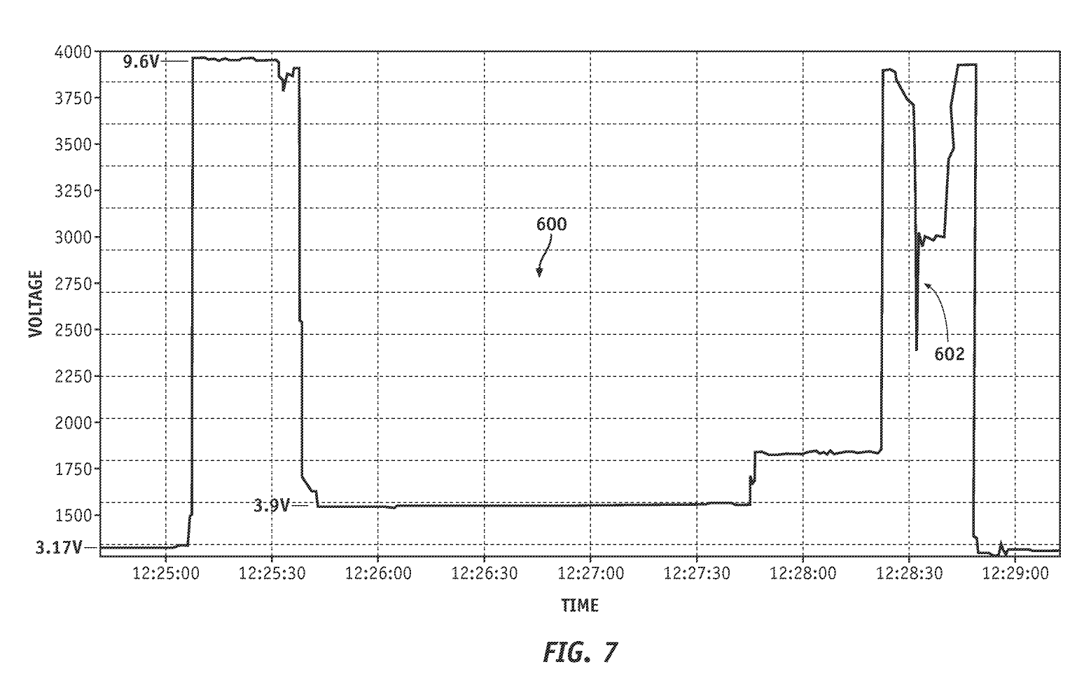

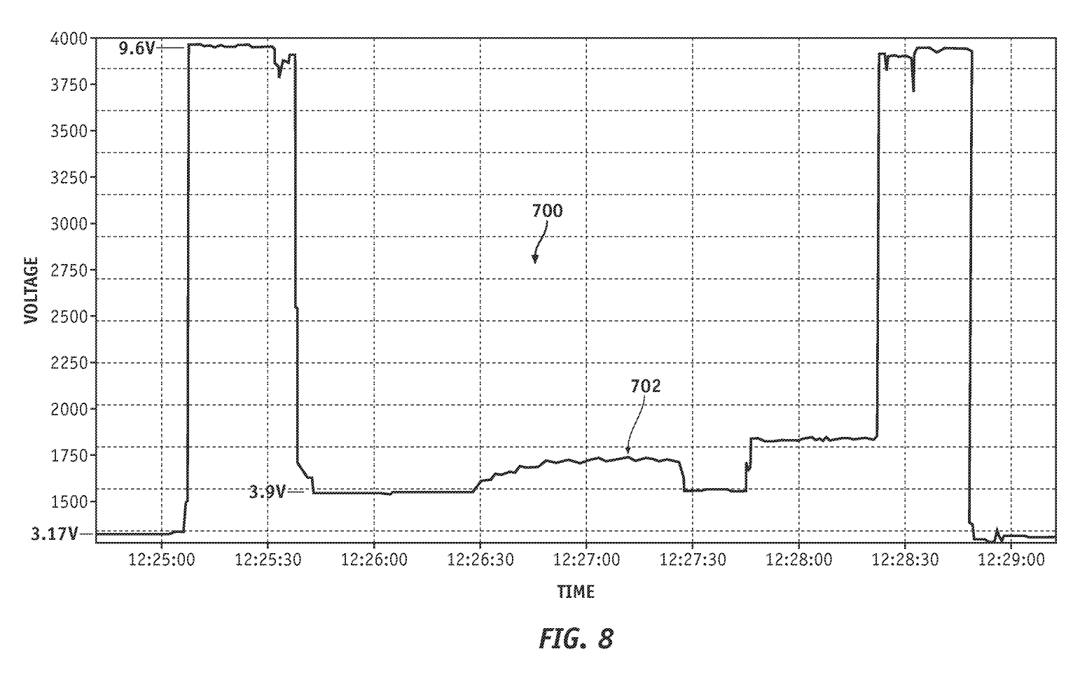

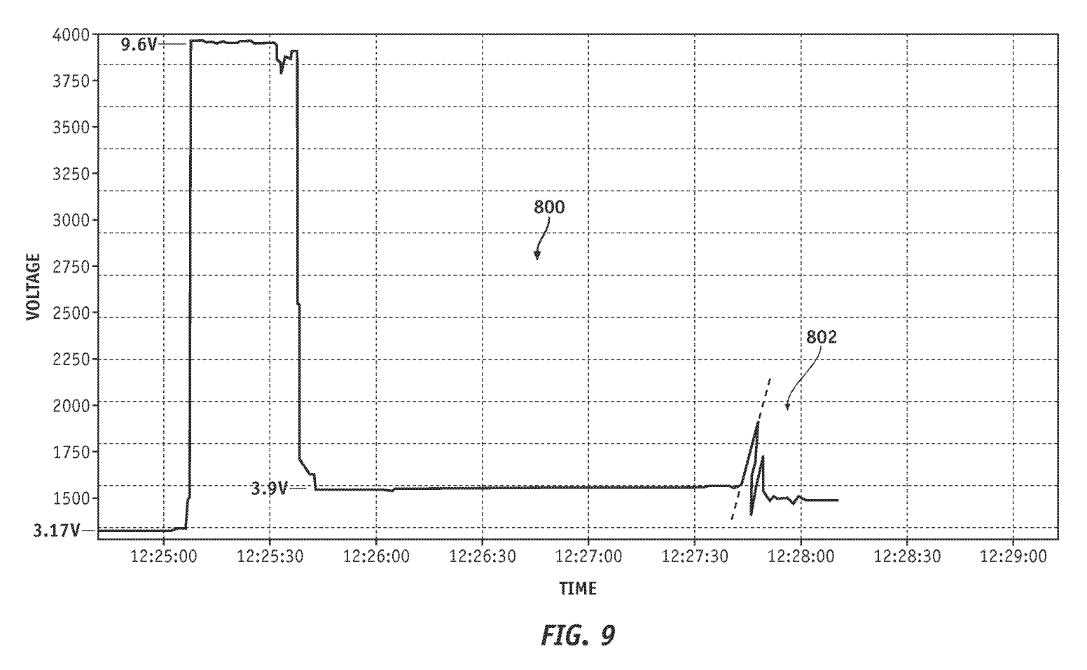

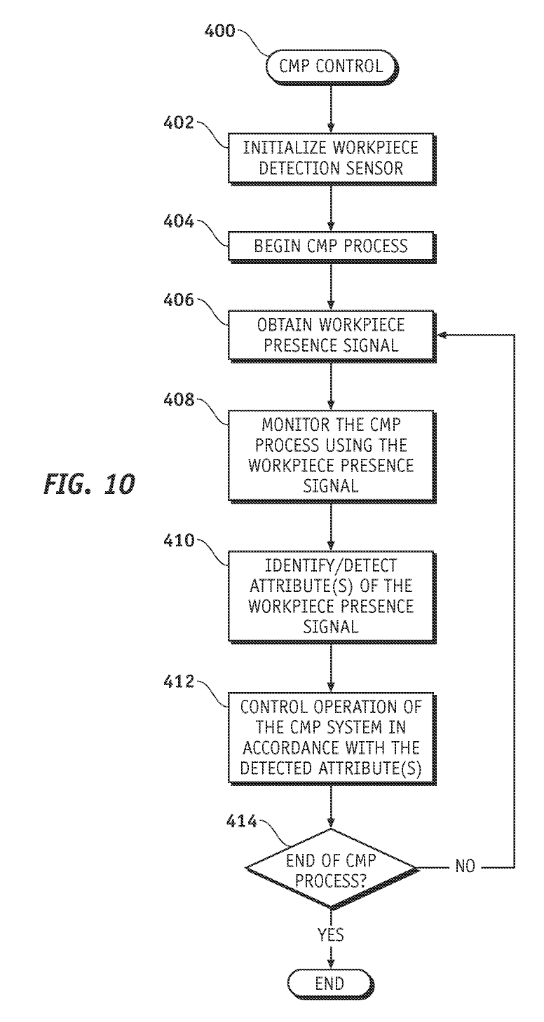

FIG. 6 is a graph that shows a typical plot of detection sensor output versus time for a CMP procedure, and FIGS. 7-9 are graphs that highlight different detectable attributes of a workpiece presence signal. More specifically, FIG. 7 is a graph that shows a typical plot of detection sensor output versus time for a CMP procedure during which the wafer is almost lost prior to unloading, FIG. 8 is a graph that shows a typical plot of detection sensor output versus time for a CMP procedure during which the wafer separates from the polishing pad, and FIG. 9 is a graph that shows a typical plot of detection sensor output versus time for a CMP procedure during which the wafer becomes broken. These graphs will be described in more detail in conjunction with FIG. 10, which is a flow chart that illustrates an embodiment of a CMP control procedure 400. The various tasks performed in connection with procedure 400 may be performed by software, hardware, firmware, or any combination thereof For illustrative purposes, the following description of procedure 400 may refer to elements mentioned above in connection with FIGS. 1-3. In practice, portions of procedure 400 may be performed by different elements of the described system, e.g., the workpiece detection sensor, the processing architecture, or another component of the CMP system itself. It should be appreciated that procedure 400 may include any number of additional or alternative tasks, the tasks shown in FIG. 10 need not be performed in the illustrated order, and procedure 400 may be incorporated into a more comprehensive procedure or process having additional functionality not described in detail herein.

CMP control procedure 400 may begin by initializing the workpiece detection sensor (task 402). This may involve calibration if needed and the generation and application of an excitation signal for the workpiece detection sensor. Notably, task 402 may be performed prior to the actual CMP routine. Once the CMP procedure begins (task 404), procedure 400 obtains a workpiece presence signal that originates from the sensor (task 406). As mentioned above, the workpiece presence signal indicates the proximity of the workpiece relative to the respective carrier head of the CMP system. Procedure 400 can monitor the CMP procedure using this workpiece presence signal (task 408) and/or identify one or more attributes of the workpiece presence signal (task 410), where such attributes are indicative of the CMP procedure status of the workpiece.

CMP control procedure 400 may then control the operation of the CMP system in a manner dictated by the detected attribute(s) of the workpiece presence signal (task 412). Thus, the CMP system may be controlled to respond in a certain way, depending upon the results of task 410. A number of detectable attributes and the manner in which task 412 responds to such attributes will be described below with reference to FIGS. 6-9. If the CMP procedure is at an end (query task 414), then procedure 400 ends or it may be repeated for another wafer. If the CMP procedure has not ended, then procedure 400 may be reentered at an appropriate location, such as task 406.

Referring to FIG. 6, a typical workpiece presence signal 500 (in the form of voltage versus time) for a CMP procedure is depicted. This plot is merely one representative output, and the actual shape and characteristics of a workpiece presence signal can vary from system to system and from workpiece to workpiece. For this example, signal 500 ranges from a low value of about 3.17 volts to a high value of about 9.6 volts. The absolute voltage values depend on many factors, including sensor type and manufacturer, physical sensor location in the carrier, presence or composition of bladder, type of workpiece, amplifier presence and settings, and other system parameters. The low value corresponds to the workpiece unloaded status, and the high value corresponds to the workpiece loaded status. The timeframe depicted in FIG. 6 spans one CMP cycle.

As explained above, certain traits, attributes, and/or characteristics of signal 500 can be analyzed and monitored for purposes of controlling the CMP system. Beginning at the left side of signal 500, the relatively stable low voltage value indicates a wafer unloaded status 502. For this example, a reading of about 3.17 volts indicates that no wafer is present. Accordingly, if the system obtains a reading above a certain calibrated threshold voltage (e.g., 3.5 volts), then it might conclude that “wafer unloaded” is not true. Conversely, if the system obtains a reading below a certain calibrated threshold voltage (e.g., 3.2 volts), then it might conclude that “wafer unloaded” is true. In practice, multiple threshold values may be employed for purposes of generating warning messages, error messages, process commands, or the like.

The upward rise in signal 500 is caused by the loading of the wafer onto the carrier head. The relatively stable high voltage value indicates a properly loaded wafer status 504. For this example, a reading of about 9.6 volts indicates that the wafer has been properly loaded. Accordingly, if the system obtains a reading below a certain calibrated threshold voltage (e.g., 8.0 volts), then it might conclude that “wafer loaded” is not true. Conversely, if the system obtains a reading above a certain calibrated threshold voltage (e.g., 9.0 volts), then it might conclude that “wafer loaded” is true. In practice, multiple threshold values may be employed for purposes of generating warning messages, error messages, process commands, or the like.

Another detectable attribute shown in FIG. 6 is a slight reduction in signal 500 following a confirmation that the wafer is properly loaded. This slight reduction corresponds to the moment when the carrier head moves towards the polishing platen and the wafer contacts the polishing pad. Reference number 506 indicates this contact time. Shortly thereafter, the CMP system performs “burping” to eject any air/gas from between the wafer and the polishing pad. This burping step is accomplished by sequentially pressurizing the plenums, beginning at the center of the carrier head. In turn, signal 500 develops attributes indicative of such burping. Reference number 508 indicates the burping procedure. Signal 500 varies slightly during this time (with a rising trend) because different zones of the wafer are pushed away from the workpiece detection sensor in a sequential manner.

The downward fall in signal 500 following the burping cycle corresponds to the beginning of the polishing process itself Signal 500 falls to about 3.9 volts because the carrier head inflates its bladder (i.e., the independent pressurizable plenums) to press the wafer against the polishing pad. This inflation causes the wafer to move away from the workpiece detection sensor. The period during which signal 500 is relatively stable at 3.9 volts indicates the polishing procedure 510. At the conclusion of the polishing procedure 510, the CMP system may perform a wafer purge to loosen the wafer from the polishing pad. Wafer purging may be accomplished by delivering water through holes in the polishing pad. Alternatively, wafer purging may be accomplished by delivering water to the surface of the polishing pad using a suitable conduit. Wafer purging typically causes the wafer to move slightly towards the workpiece detection sensor. Accordingly, signal 500 rises a bit at the beginning of wafer purging. Reference number 512 indicates the wafer purging procedure.

The significant rise in signal 500 following the wafer purge corresponds to the carrier head acquiring the wafer by deflating the bladder. In other words, the wafer resumes its loaded state. The carrier head typically moves away (e.g., raises up) from the polishing platen at this time. This wafer acquisition status is identified by reference number 514. Thereafter, the drop in signal 500 corresponds to unloading of the wafer (reference number 516). As depicted in FIG. 6, wafer unloading 516 at the end of the CMP procedure returns signal 500 to the low voltage level (e.g., 3.17 volts).

As illustrated by the example of FIG. 6, attributes or characteristics of the workpiece presence signal can be analyzed to determine a workpiece loaded status, a workpiece unloaded status, and/or a particular workpiece in-process status. In this regard, a workpiece in-process status can be, without limitation: a workpiece burping status; a workpiece polishing status; or a workpiece purge status. The workpiece detection sensor is suitably configured to produce an output signal having characteristics indicative of these different statuses under normal operating conditions.

The workpiece presence signal may also be utilized to detect abnormal operating conditions or statuses that might arise during the CMP procedure. For example, it is possible to detect when the carrier head loses or almost loses acquisition of the workpiece. In this regard, FIG. 7 depicts a workpiece presence signal 600 for a CMP procedure during which the wafer is almost lost prior to unloading. Many of the traits and characteristics of signal 600 were described above in the context of signal 500 (FIG. 6). Such common features and characteristics will not be redundantly described here for signal 600.

Signal 600 includes a downward spike 602 prior to wafer unloading. This spike 602 indicates that full acquisition of the wafer was temporarily lost. However, the wafer was reacquired before becoming unloaded. If this type of downward spike is detected during a period when the wafer is normally expected to be loaded, then the system can take corrective action. For example, the system might initiate a wafer reacquisition routine or it may move the wafer towards the polishing platen. Thus, FIG. 7 illustrates a situation where attributes of the workpiece presence signal indicate a workpiece loss warning status and trigger a process command.

As another example, it is possible to detect when the wafer separates or “floats” from the polishing pad during the polishing step (i.e., if “hydroplaning” occurs). In this regard, FIG. 8 depicts a workpiece presence signal 700 for a CMP procedure during which the wafer separates from the polishing pad. Many of the traits and characteristics of signal 700 were described above in the context of signal 500 (FIG. 6). Such common features and characteristics will not be redundantly described here for signal 700.

Signal 700 includes a discontinuity 702 (e.g., a bulge) during the polishing procedure. This discontinuity 702 indicates that the wafer has drifted away from the polishing pad and toward the workpiece presence sensor. However, the wafer was eventually forced against the polishing pad for completion of the polish. If this type of discontinuity is detected during the polishing period, then the system can take corrective action. For example, the system might terminate the polishing step, double check the pressure applied by the carrier head, increase the pressure applied by the carrier head, perform burping of the wafer, or the like. Thus, FIG. 8 illustrates a situation where attributes of the workpiece presence signal indicate a workpiece separation during polishing status.

As another example, it is possible to detect when a wafer breaks during the polishing step. In this regard, FIG. 9 depicts a workpiece presence signal 800 for a CMP procedure during which the wafer becomes broken. Many of the traits and characteristics of signal 800 were described above in the context of signal 500 (FIG. 6). Such common features and characteristics will not be redundantly described here for signal 600.

Signal 800 includes a discontinuity 802 that occurs during the polishing procedure. This discontinuity 802 indicates that the wafer may be broken. If this type of discontinuity is detected during the polishing period, then the system can take corrective action. For example, the system might terminate the polishing immediately to prevent damage to the CMP system components. Thus, FIG. 9 illustrates a situation where attributes of the workpiece presence signal indicate a broken workpiece status. In practice, the detected attribute may correspond to a variation in the baseline voltage that is expected during the polishing period. Alternatively (or additionally), the detected attribute may be a slope in signal 800 that exceeds a threshold slope. For this embodiment, the slope of signal 800 during a normal polishing period will be relatively low (ideally, zero). However, if the wafer breaks during polishing, then the slope of signal 800 may increase significantly (positively or negatively) in a very short period of time. For this example, the system may be configured to detect the slope indicated by the dashed line in FIG. 9.

As illustrated by the above examples, attributes or characteristics of the workpiece presence signal can be analyzed to determine abnormal or unusual operating conditions or statuses of the CMP system and initiate corrective or responsive actions. The attribute(s) may be indicative of the following, without limitation: improper loading of the workpiece on the carrier head; a broken workpiece occurring during polishing; lost acquisition of the workpiece during loading/unloading; workpiece separation from the polishing pad; or the like. The workpiece detection sensor is suitably configured to produce an output signal having characteristics indicative of these different statuses. Referring again to FIG. 10, task 412 may be influenced by the detected attribute(s). For instance, if the workpiece presence signal indicates improper loading of a wafer, then CMP control procedure 400 may generate an appropriate warning message, an alert, an indicator flag, or the like. Alternatively (or additionally), procedure 400 may initiate reloading of the wafer on the carrier head in an attempt to correct the problem. As another example, if the workpiece presence signal indicates lost acquisition of the wafer during unloading, then procedure 400 might terminate the unloading procedure and/or attempt to reacquire the wafer before proceeding. As yet another example, if the workpiece presence signal indicates a potentially broken workpiece during polishing, then procedure 400 might terminate the polishing procedure.

It should be appreciated that a workpiece presence signal having a continuous analog output (as described herein) could also be used to detect or calculate the process endpoint dynamically, to determine when the procedure needs to transition from one state to another state (e.g., a “bulk” polish process to a “soft” polish process), to determine whether it is necessary to adjust the pressure in the bladder of the carrier head, to dynamically adjust the CMP process recipe, or the like. Moreover, the techniques and methodologies described here could also be combined with other CMP monitoring and control systems, e.g., endpoint detection (for example, optical reflectivity measurements), film thickness measurement (for example, eddy current measurements), or the like.

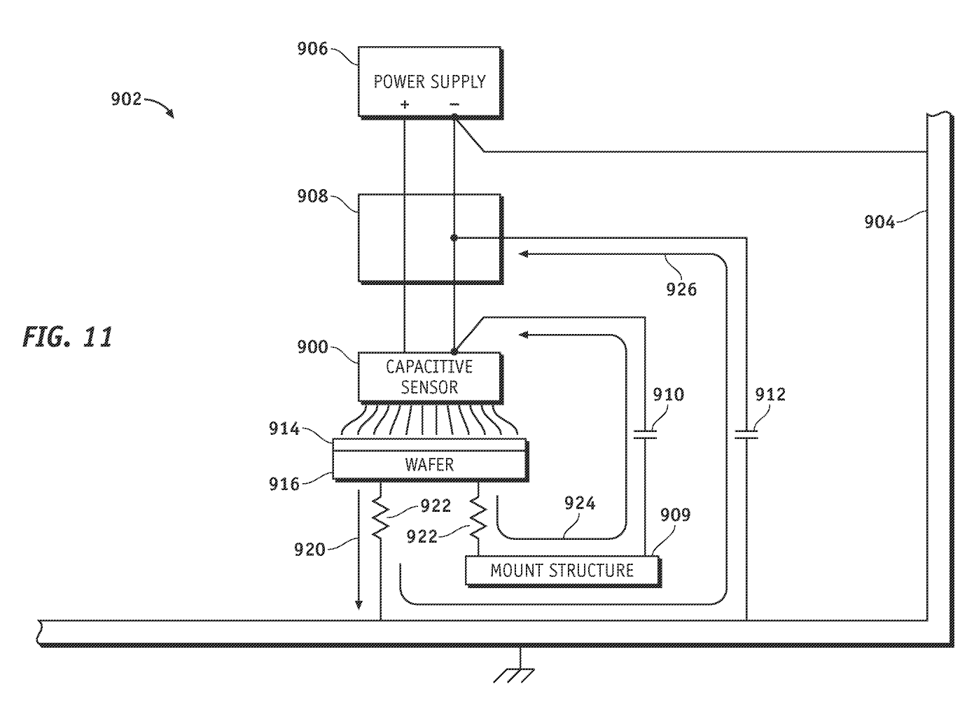

As mentioned above, certain embodiments of a CMP may utilize a capacitive sensor that generates an analog output that indicates the presence of a wafer. FIG. 11 is a schematic circuit diagram that illustrates an exemplary capacitive sensor 900 deployed in a CMP system 902. FIG. 11 depicts a portion of the system chassis 904 of CMP system 902. The electrical potential of system chassis 904 represents chassis ground of CMP system 902. CMP system 902 also includes, without limitation: a power supply 906; a driver circuit 908 for capacitive sensor 900; conductive mounting structure 909; and capacitors 910/912. Although not separately shown in FIG. 11, CMP system 902 includes a carrier head (configured as described above) that serves as a mounting platform for capacitive sensor 900. In this embodiment, the carrier head includes a bladder 914 that facilitates holding and processing of a wafer 916. In addition, mounting structure 909 is configured as a mount plate for the carrier head and associated pneumatic assembly. In practice, mounting structure 909, capacitive sensor 900, bladder 914, and the carrier head itself move and rotate together during operation of CMP system 902.

Power supply 906, which provides 24 VDC in certain embodiments, has a positive terminal coupled to driver circuit 908, and a negative terminal coupled to system chassis 904 (which provides chassis ground). Driver circuit 908 may be implemented as a printed circuit assembly, a printed circuit board, or the like. Driver circuit 908, which is powered by power supply 906, is suitably configured to generate the activation signals for capacitive sensor 900. In addition, driver circuit 908 is suitably configured to receive and process the return signals from capacitive sensor 900. In certain embodiments, driver circuit 908 may include or cooperate with an impedance isolation circuit or arrangement. The impedance isolation circuit may be utilized in implementations where the capacitive sensor has a low output impedance and the corresponding analog input circuit has a low input impedance. In practice, the impedance isolation circuit may employ an operational amplifier between the output of the capacitive sensor and the analog input circuit.

Capacitor 910 is connected between mounting structure 909 and the common (ground) terminal of capacitive sensor 900. This may be accomplished using cabling, wiring, and suitable connection terminals. For one embodiment, capacitor 910 is a 47 nF capacitor. In this embodiment, capacitor 912 is connected between system chassis 904 and the common (ground) terminal of driver circuit 908. This may be accomplished using cabling, wiring, and suitable circuit board connection terminals. For one embodiment, capacitor 912 is a 47 nF capacitor. Capacitors 910/912 provide AC current paths for power supply 906 that enhance the quality and stability of the sensor signals. For example, during operation of CMP system 902, some AC current follows a path (represented by reference number 920) from capacitive sensor 900, to wafer 916, through the water 922 maintained by CMP system 902, and to system chassis 904. FIG. 11 depicts the water 922 as a resistance between wafer 916 and system chassis 904. In addition, some AC current follows a path (represented by reference number 924) from capacitive sensor 900, to wafer 916, through the water 922, to conductive mounting structure 909, and through capacitor 910, which is terminated at the ground of capacitive sensor 900. Furthermore, some AC current follows a path (represented by reference number 926) from capacitive sensor 900, to wafer 916, through the water 922, to system chassis 904, and through capacitor 912, which is terminated at the ground of driver circuit 908.

This circuit arrangement and the use of capacitors 910/912 results in the return of more AC current (used to drive capacitive sensor 900) to power supply 906. This reduces noise in the measured sensor signal and improves the accuracy of the presence detection described above. Capacitors 910/912 remain in their respective conductive paths regardless of whether the carrier head is rotating, thus providing consistent output signal quality throughout the CMP cycle.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A carrier head for supporting a workpiece, the carrier head comprising:
a body;
a structure coupled to the body, the structure being configured to hold a workpiece; and
a capacitive sensor coupled to the body, the capacitive sensor being configured to generate an analog output that indicates workpiece presence status relative to the carrier head.

2. The carrier head of claim 1, wherein the workpiece presence status comprises a workpiece unloaded status, a workpiece loaded status, and at least one workpiece in-process status.

3. The carrier head of claim 1, the analog output of the capacitive sensor being insensitive to the presence of water.

4. The carrier head of claim 1, the capacitive sensor being configured to generate an output voltage having a magnitude that varies with the distance between the workpiece and the capacitive sensor.

5. The carrier head of claim 1, the capacitive sensor being configured to generate a continuous range of output voltages between a first voltage corresponding to the workpiece unloaded status and a second voltage corresponding to the workpiece loaded status.

6. The carrier head of claim 1, wherein:
the at least one workpiece in-process status includes a workpiece burping status; and
the capacitive sensor is configured to generate an output signal having characteristics indicative of the workpiece burping status.

7. The carrier head of claim 1, wherein:
the at least one workpiece in-process status includes a workpiece polishing status; and
the capacitive sensor is configured to generate an output signal having characteristics indicative of the workpiece polishing status.

8. The carrier head of claim 1, wherein:
the at least one workpiece in-process status includes a workpiece purge status; and
the capacitive sensor is configured to generate an output signal having characteristics indicative of the workpiece purge status.

9. The carrier head of claim 1, wherein:
the at least one workpiece in-process status includes a workpiece loss warning status; and
the capacitive sensor is configured to generate an output signal having characteristics indicative of the workpiece loss warning status.

10. The carrier head of claim 1, wherein:
the at least one workpiece in-process status includes a workpiece separation during polishing status; and
the capacitive sensor is configured to generate an output signal having characteristics indicative of the workpiece separation during polishing status.

11. The carrier head of claim 1, wherein:
the at least one workpiece in-process status includes a broken workpiece status; and
the capacitive sensor is configured to generate an output signal having characteristics indicative of the broken workpiece status.

12. A method of controlling a chemical mechanical planarization (CMP) procedure for a workpiece, the method comprising:
obtaining a workpiece presence signal that indicates proximity of the workpiece to a carrier head of a CMP system;
identifying an attribute of the workpiece presence signal, the attribute being indicative of a CMP procedure status of the workpiece; and
controlling operation of the CMP system in a manner dictated by the attribute.

13. The method of claim 12, further comprising monitoring the CMP procedure using the workpiece presence signal.

14. The method of claim 12, wherein:
the attribute is indicative of improper loading of the workpiece on the carrier head; and
controlling operation of the CMP system comprises generating a warning of improper loading.

15. The method of claim 12, wherein:
the attribute is indicative of improper loading of the workpiece on the carrier head; and
controlling operation of the CMP system comprises initiating reloading of the workpiece on the carrier head.

16. The method of claim 12, wherein:
the attribute is indicative of a broken workpiece occurring during polishing of the workpiece; and
controlling operation of the CMP system comprises terminating polishing of the workpiece.

17. The method of claim 16, wherein the attribute is a slope in the workpiece presence signal that exceeds a threshold slope.

18. The method of claim 12, wherein:
the attribute is indicative of lost acquisition of the workpiece during unloading of the workpiece; and
controlling operation of the CMP system comprises terminating unloading of the workpiece.

19. The method of claim 12, wherein the attribute is indicative of workpiece separation from a polishing pad during polishing of the workpiece.

20. The method of claim 12, further comprising generating the workpiece presence signal with a capacitive sensor in the carrier head, the capacitive sensor being configured to generate an analog output that indicates wafer presence status.

21. The method of claim 20, wherein generating the workpiece presence signal comprises generating an output voltage having a magnitude that varies with the distance between the workpiece and the capacitive sensor.

22. The method of claim 20, wherein generating the workpiece presence signal comprises generating a continuous range of output voltages between a first voltage corresponding to a workpiece unloaded status and a second voltage corresponding to a workpiece loaded status.

23. A chemical mechanical planarization (CMP) system comprising:
a polishing pad for polishing a workpiece;
a carrier head configured to hold the workpiece against the polishing pad during planarization, and to hold the workpiece during transport to and from the polishing pad;
a capacitive sensor coupled to the carrier head and configured to produce a workpiece presence signal that indicates proximity of the workpiece to the carrier head; and
a processing architecture coupled to the capacitive sensor and configured to receive the workpiece presence signal, detect CMP procedure related attributes of the workpiece presence signal, and control operation of the CMP system in response to detected CMP procedure related attributes.

24. The CMP system of claim 23, the capacitive sensor being configured to generate an output voltage having a magnitude that varies with the distance between the workpiece and the capacitive sensor.

25. The CMP system of claim 23, the capacitive sensor being configured to generate a continuous range of output voltages between a first voltage corresponding to a workpiece unloaded status and a second voltage corresponding to a workpiece loaded status.

26. The CMP system of claim 23, the processing architecture being configured to detect abnormal operating conditions during a CMP procedure, using the workpiece presence signal.
